(19) United States
(12) Patent Application Publication
(10) Pub. No.: US 2020/0365540 A1
(43) Pub. Date: Nov. 19, 2020

(54) METHOD OF SELF-ASSEMBLY WITH A HYBRID MOLECULAR BONDING

(71) Applicant: Commissariat à l'Energie Atomique et aux Energies Alternatives, Paris (FR)

(72) Inventors: Amandine JOUVE, Grenoble (FR); Emmanuel OLLIER, Grenoble (FR); Emmanuel ROLLAND, Grenoble (FR); Ulrich SOUPREMANIEN, Grenoble (FR)

(21) Appl. No.: 16/851,412

(22) Filed: Apr. 17, 2020

(30) Foreign Application Priority Data
May 15, 2019 (FR) 1905061

(51) Int. Cl. H01L 23/00; H01L 23/498

(52) U.S. Cl. CPC H01L 24/08; H01L 23/49811; H01L 24/89; H01L 24/03; H01L 23/49822; H01L 2224/80896; H01L 2224/03614; H01L 2224/03616; H01L 2224/0382; H01L 2224/08238; H01L 2224/80895; H01L 23/49838

(57) ABSTRACT

The present disclosure relates to a method of manufacturing a first electronic circuit including a planar surface, intended to be affixed to a second electronic circuit by a self-assembly method with a hybrid molecular bonding, and first electrically-conductive pads exposed on the surface. The method includes the forming of a peripheral area around the surface including second exposed and raised pads, each at least partly having the same composition as the first pads.

### FIELD

The present disclosure generally relates to a method of hybrid molecular bonding of electronic circuits and an electronic circuit enabling to implement such a method.

### BACKGROUND

For certain applications, an electronic circuit or a plurality of electronic circuits, for example, integrated circuits, are affixed to a support by molecular bonding. The support for example corresponds to another integrated circuit. Before bonding the integrated circuit to the support, it is necessary to correctly place the integrated circuit with respect to the support. This may be done by a method of self-assembly of the integrated circuit to the support.

FIGS. 1 to 3 show, in their left-hand portion, cross-section views and, in their right-hand portion, partial simplified top views, of structures obtained at successive steps of an example of a method of self-assembly of an electronic circuit 10, for example, an integrated circuit, to a support 11.

Support 11 has at its upper surface an assembly area 14 of high wettablity surrounded with a peripheral area 12 of low wettability. Support 11 may comprise a plurality of assembly areas 14. A drop 16 of a liquid, for example, demineralized water, is arranged on assembly area 14 (FIG. 1).

Generally, the wettability of a material may be characterized by the contact angle θ of a liquid drop on the material. The smaller the contact angle, the greater the wettability of the material. In the cross-section plane of FIG. 1, the liquid/air interface 18 of drop 16 is in contact with assembly area 14 at contact points P and P′. Call T the tangent to interface 18 at contact point P (or P′). The angle of contact θ of drop 16 on assembly area 14 is the angle between tangent T and the surface of assembly area 14 which is substantially horizontal. When drop 16 is at rest, the measured angle θ is the static contact angle.

Electronic circuit 10 is then taken closer to assembly area 14 until it comes into contact with drop 16. In such an approach phase, electronic circuit 10 may be shifted and inclined with respect to assembly area 14 (FIG. 2).

The forces exerted by drop 16 on electronic circuit 10 then displace electronic circuit 10 to the desired alignment relative to the assembly area 14 (FIG. 3) without for any external action to be necessary.

The method of affixing electronic circuit 10 to support 11, for example, by hybrid molecular bonding, can then be implemented. The hybrid molecular bonding enables to stack electronic circuits on one another with an electric interconnection between them.

For the self-assembly method to take place properly, it is necessary for drop 16 to remain confined on assembly area 14 all along the alignment of electronic circuit 10 relative to support 11. In the previously-described example of self-assembly method, the confinement of drop 16 on assembly area 14 all along the self-assembly method is obtained by the wettability difference between assembly area 14 and peripheral area 12. The higher the wettability difference, the more drop 16 tends to remain confined on assembly area 14.

However, with known methods, it may be difficult to obtain a significant wettability difference between assembly area 14 and peripheral area 12. Errors in the placing of drop 16 on support 11 may then occur and drop 16 may leave assembly area 14 during the self-assembly method.

There thus is a need to improve the confinement of liquid drops on a support for the implementation of a self-assembly method.

It is further desirable for the pad manufacturing method to be compatible with conventional electronic circuit manufacturing techniques.

### SUMMARY

An object of an embodiment is to overcome all or part of the disadvantages of known supports comprising assembly areas for the implementation of a self-assembly method and of known methods of manufacturing such supports.

Another object of an embodiment is to improve the confinement of liquid drops on assembly areas of a support for the implementation of a self-assembly method.

Another object of an embodiment is to increase the wettability difference between each assembly area and the peripheral area surrounding the assembly area.

Another object of an embodiment is for the increase in the wettability difference between each assembly area and the peripheral area surrounding the assembly area to be obtained without adding new steps to the known steps of an electronic circuit manufacturing method.

Another object of an embodiment is for the assembly area manufacturing method to be compatible with conventional electronic circuit manufacturing methods.

For this purpose, an embodiment provides a first electronic circuit comprising a first planar surface, intended to be affixed to a second electronic circuit by a self-assembly method with a hybrid molecular bonding, first electrically-conductive pads exposed on the first surface, the first electronic circuit further comprising a peripheral area around the first surface comprising second exposed and raised pads, each at least partly having the same composition as the first pads.

An embodiment also provides a method of manufacturing a first electronic circuit comprising a first planar surface, intended to be affixed to a second electronic circuit by a self-assembly method with a hybrid molecular bonding, and first electrically-conductive pads exposed on the first surface, the method comprising the forming of a peripheral area around the first surface comprising second exposed and raised pads, each at least partly having the same composition as the first pads.

According to an embodiment, the method comprises a step of chemical-mechanical planarization to form a third planar surface of an electrically-insulating layer having the first pads and the second pads exposed thereon and a step of etching the insulating layer around the second pads to delimit the first surface.

According to an embodiment, the method comprises a step of covering the assembly surface with a resin layer, the deposition of a hydrophobic layer on the second pads, and the removal of the resin layer.

An embodiment also provides a method of self-assembly with a hybrid bonding of the first planar surface of a first electronic circuit manufactured as previously described to a second surface of a second electronic circuit, the second electronic circuit comprising third electrically-conductive pads exposed on the second surface, the method comprising the deposition of a drop of a liquid on the first surface and the placing into contact of the second surface with said drop.

According to an embodiment, the third pads are arranged symmetrically with respect to the first pads.

According to an embodiment, the second pads each comprise a hydrophobic coating.

According to an embodiment, the second pads are arranged all around the first surface.

According to an embodiment, the peripheral area comprises at least one raised track surrounding the first surface, the track at least partly having the same composition as the first pads.

According to an embodiment, the peripheral area comprises, around the first surface, raised bars extending perpendicularly to the edges of the first surface, each bar at least partly having the same composition as the first pads.

According to an embodiment, the tops of the second pads are recessed with respect to the first surface.

According to an embodiment, the ratio of the surface area of the first pads, seen perpendicularly to the first surface, to the surface area of the first surface is different from the ratio of the surface area of the second pads, seen perpendicularly to the peripheral area, to the surface area of the peripheral area.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows, in its right-hand portion, a cross-section view and, in its left-hand portion, a partial simplified top view, of a structure obtained at a step of an example of a method of self-assembly of an electronic circuit on a support;

FIG. 2 is a drawing similar to FIG. 1 of a structure obtained at a subsequent step of the method;

FIG. 3 is a drawing similar to FIG. 1 of a structure obtained at a subsequent step of the method;

FIG. 4 is a partial simplified top view of an embodiment of an electronic circuit adapted to the carrying out of a self-assembly and molecular bonding method;

FIG. 5 is a partial simplified cross-section view of the electronic circuit of FIG. 4;

FIG. 6 is a partial simplified cross-section view of a variant of the electronic circuit of FIG. 4;

FIG. 7 is a detail view of FIG. 5 showing a drop of liquid resting on the electronic circuit outside of the assembly area;

FIG. 8 is a top detail view of FIG. 5;

FIG. 9 is a side detail view of FIG. 5;

FIG. 10 is a drawing similar to FIG. 4 of another embodiment of an electronic circuit adapted to the carrying out of a self-assembly and molecular bonding method;

FIG. 11 is a drawing similar to FIG. 4 of another embodiment of an electronic circuit adapted to the carrying out of a self-assembly and molecular bonding method;

FIG. 12 is a partial simplified cross-section view of the structure obtained at a step of an embodiment of a method of manufacturing an electronic device comprising the electronic circuit shown in FIGS. 4 and 5;

FIG. 13 illustrates another step of the method;

FIG. 14 illustrates another step of the method;

FIG. 15 illustrates another step of the method;

FIG. 16 illustrates another step of the method;

FIG. 17 illustrates another step of the method; and

FIG. 18 illustrates another step of the method.

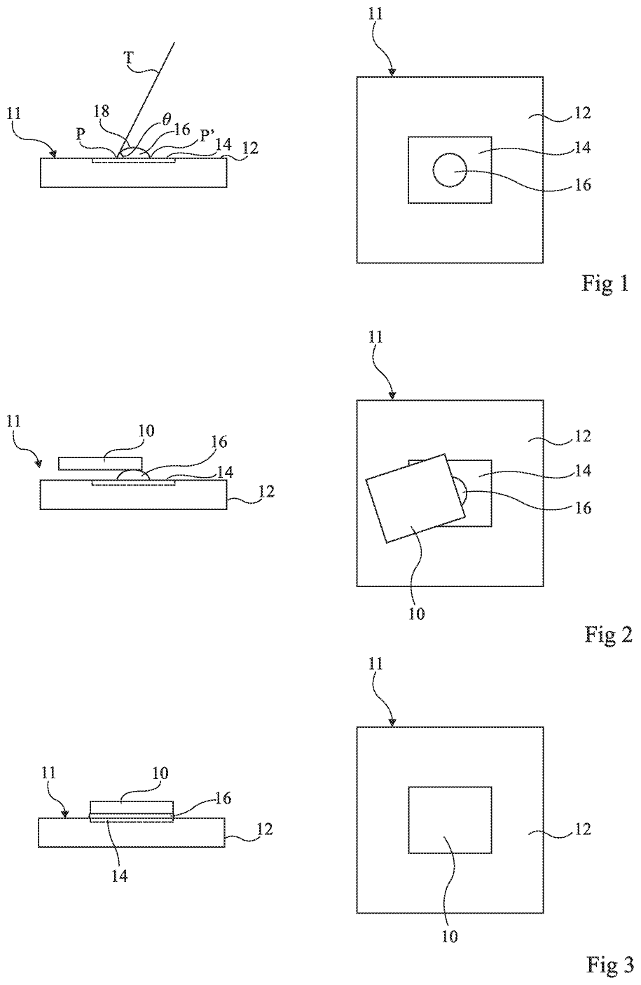

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an electronic circuit in a normal position of use. Unless specified otherwise, the expressions “around”, “approximately”, “substantially” and “in the order of” signify within 10%, and preferably within 5%. In the following description, the term “conductor” means electrically conductive and the term “insulating” means electrically insulating.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, in the following description, the term “material of high wettability” with respect to a liquid, for example, water, designates a material for which the static contact angle of a drop of the liquid on the material is smaller than 90° and the term “material of low wettability” with respect to a liquid designates a material for which the static contact angle of a drop of the liquid on the material is greater than 90°. In the case where the liquid is water, a material of high wettability is also called hydrophilic and a material of low wettability is also called hydrophobic.

Hybrid molecular bonding enables to manufacture an electronic device comprising a first electronic circuit affixed to a second electronic circuit with an electric interconnection between the first and second electronic circuits, the first electronic circuit for example corresponding to an integrated circuit chip and the second electronic circuit for example corresponding to an interposer circuit. An example of a method of manufacturing the electronic device comprises the forming of first and second integrated circuit wafers, each comprising an assembly surface corresponding to the free surface of an insulating layer having conductive pads flush therewith. At least the second integrated circuit wafer is then cut to form different integrated circuit chips. One of the chips is then affixed to the first wafer by hybrid molecular bonding, placing in contact the conductive pads and the insulating layers of the chip assembly surface and of the first wafer. The first wafer may then be cut to separate the electronic devices.

The obtaining of a surface state adapted to the carrying out of a molecular bonding generally implies a step of chemical mechanical planarization of the integrated circuit wafers, also called CMP, which generally combines a chemical and a mechanical etching. Such a method may require for the different materials present at the surface of the integrated circuit wafers to be substantially homogeneously distributed. Thereby, conductive pads of same dimensions, for example, of square or hexagonal shape, substantially homogeneously distributed all over the surface having the CMP performed thereon, are generally used for each wafer.

According to an embodiment, to increase the wettability difference between the assembly area and the peripheral area surrounding the area of assembly of the first electronic circuit, after the CMP has been carried out, the insulating layer located between the conductive pads of the peripheral area is partially etched to partially expose the conductive pads of the peripheral area. The pads thus exposed form raised areas which decrease the wettability of the peripheral area and thus increase the wettability difference between the assembly area and the peripheral area if the dimensions and the distribution of the pads respect the criteria described in the following description.

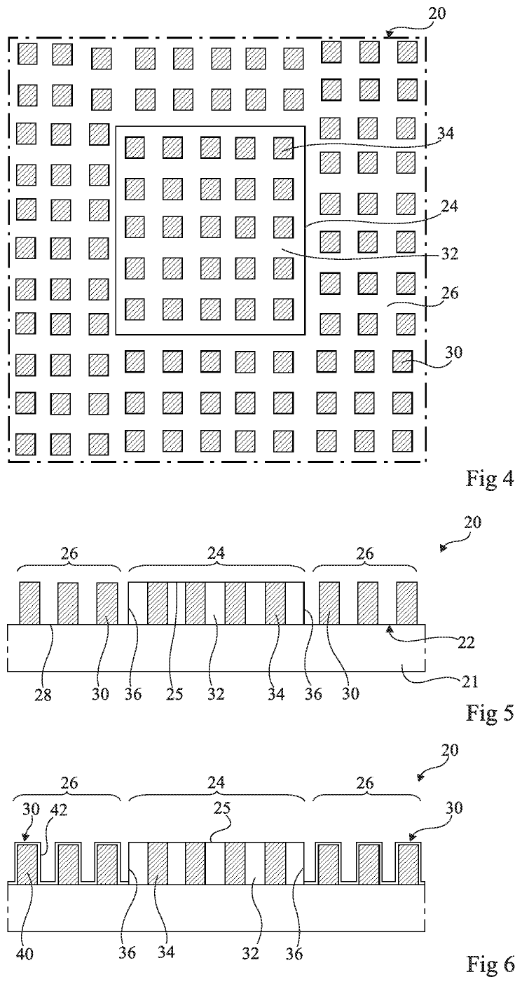

FIGS. 4 and 5 respectively are a top view and a cross-section view, partial and simplified, of an embodiment of a first electronic circuit 20, for example, an interposer or an integrated circuit chip, having at least one second electronic circuit, not shown, for example, an integrated circuit chip, intended to be affixed thereto by a self-assembly method comprising a hybrid bonding step. Electronic circuit 20 is only partially shown in the drawings.

Electronic circuit 20 comprises an electronic circuit bulk 21 and an upper surface 22. Upper surface 22 comprises an assembly area 24 totally surrounded with a peripheral area 26. Upper surface 22 may comprise more than one assembly area 24, each assembly area being then surrounded with a peripheral area 26, when a plurality of electronic circuits are affixed to electronic circuit 20.

According to an embodiment, assembly area 24 comprises a substantially planar assembly surface 25. According to an embodiment, assembly surface 25 has, in top view, a shape symmetrical to that of the electronic circuit to which it is intended to be bonded.

Peripheral area 26 comprises a bottom surface 28, preferably substantially planar and recessed with respect to assembly surface 25, having conductive pads 30 projecting therefrom. Assembly surface 25 corresponds to the upper surface of an insulating layer 32, conductive pads 34, which extend in insulating layer 32, being flush with the upper surface. Bottom surface 28 may correspond to the upper surface of insulating layer 32 in peripheral area 26 or may correspond to the upper surface of another insulating layer. Peripheral area 26 may itself be surrounded with an area, not shown, which does not take part in the self-assembly method but preferably has substantially the same structure as assembly area 24 to allow the implementation of a CMP step. According to an embodiment, the distribution of pads 30 and 34 is substantially uniform all over electronic circuit 20. As a variation, the distribution of pads 30 in peripheral area 26 may be different from the distribution of pads 34 in assembly area 24. According to an embodiment, pads 30 substantially have the same dimensions as pads 34. According to another embodiment, at least some of pads 30, or even all pads 30, have dimensions different from those of pads 34.

According to an embodiment, the tops of pads 30 may be located substantially in the same plane as assembly surface 25 or recessed from this plane with respect to assembly surface 25. The distance between assembly surface 25 and bottom surface 28 may be in the range from some hundred nanometers to a few micrometers, typically from 300 nm to 5 μm. Assembly surface 25 is coupled to bottom surface 28 by sides 36 substantially perpendicular to assembly surface 25. As a variation, sides 36 may be inclined with respect to the assembly surface 25 by an angle in the range from 10° to 90°, preferably from 45° to 90°. Sides 36 may be inclined so that the cross-section of the pads increases as the distance to bottom surface 28 increases. This enables to further increase the wettablity difference between assembly area 24 and peripheral area 26.

The body 21 of electronic circuit 20 may further comprise a substrate, not shown, having electronic components, not shown, formed inside and on top thereof. The substrate may be covered with a stack, not shown, of insulating layers having metal tracks of different metallization levels and conductive vias formed thereon to connect the electronic components together and to connect them to some of pads 34. Insulating layer 32 is the insulating layer of the stack located at the top of the stack of insulating layers, opposite to the substrate.

According to an embodiment, assembly surface 25 has a high wettability, the static contact angle of a drop of liquid on assembly surface 25 being smaller than or equal to 15°, preferably smaller than or equal to 10°, more preferably smaller than or equal to 5°. As will be described in further detail hereafter, the presence of pads 30, and possibly their hydrophobic preparation, provide peripheral area 26 with a low wettability, the static contact angle of a liquid drop on peripheral area 26 being greater than or equal to 90°, preferably greater than or equal 110°. Thereby, a liquid drop deposited on assembly surface 25, during the implementation of a self-assembly method, tends not to leave assembly surface 25 for the entire duration of the self-assembly method and a liquid drop, placed partly on assembly surface 25 and partly on peripheral area 26, spontaneously displaces so that the entire water drop is located assembly surface 25.

The measurement of the wetting angle may be performed by using the measurement device commercialized by GBX under trade name Digidrop—MCAT. The measurement comprises the deposition of a drop of the liquid used during the self-assembly method, for example of demineralized water, from 2 μl to 10 μl on a surface of the material to be studied, the acquisition of an image of the drop by an image acquisition device, and the determination of the contact angle by computer analysis of the acquired image.

FIG. 6 is a drawing similar to FIG. 5 of a variant of electronic circuit 20 where each pad 30 comprises a core 40 covered with a layer 42 of a hydrophobic material. Hydrophobic layer 42 may also extend over bottom surface 28 and possibly over sides 36. In the embodiment shown in FIG. 5, pads 30 have the same composition as pads 34. In the variant illustrated in FIG. 6, the cores 40 of pads 30 have the same composition as pads 34. Pads 34 may be made of a metal or of a metallic alloy, particularly copper (Cu), aluminum (Al), titanium (Ti), or tungsten (W). Pads 34 may have a monolayer structure or correspond to a stack of at least two metal layers, for example, a Cu/Ti/TiN or Cu/Ta/TaN stack. Insulating layer 32 may be a monolayer, for example, a silicon oxide or silicon nitride layer, or may have a multilayer structure comprising a stack of insulating layers.

According to an embodiment, the hydrophobic material is a fluorinated material, preferably a fluorocarbon material. As an example, hydrophobic layer 42 is based on fluorocarbon compounds of CₓF_{y} type, where x and y are real numbers, x may vary from 1 to 5, and y may vary from 1 to 8. The thickness of hydrophobic layer 42 is for example in the range from 1 nm to 300 nm.

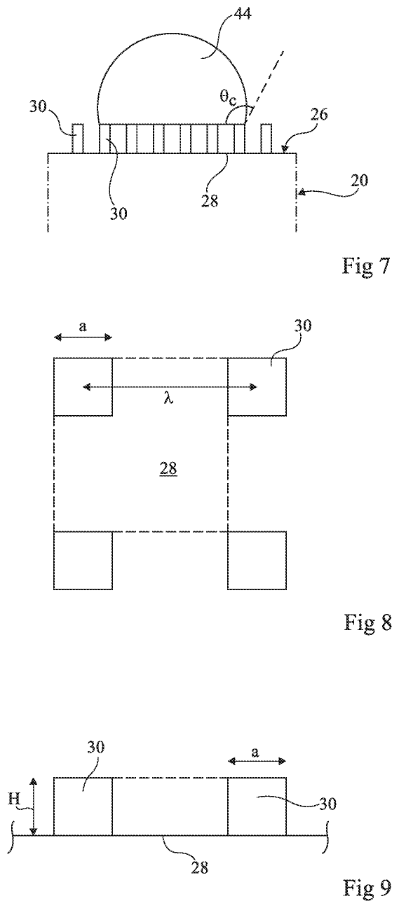

FIG. 7 is a detail view of FIG. 5, at the level of peripheral area 26, showing a liquid drop 44 resting on pads 30 in the case where there is no penetration of the liquid between pads 30 and FIGS. 8 and 9 illustrate dimensional parameters of pads 30. Three dimensional parameters of a pad 30 will now be described, knowing that such parameters may be identical or different from one pad to the other.

Call height “H” the height of pad 30. Preferably, pads 30 substantially have the same height “H”. The cross-section of each pad 30 in a plane parallel to bottom surface 28 may be substantially circular, ellipsoidal or polygonal, for example, triangular, square, or rectangular. As a variation, the cross-section of each pad 30 in a plane parallel to bottom surface 28 may have any shape. In the rest of the description, call width “a” the smallest dimension of the cross-section of pad 30 in a plane parallel to bottom surface 28. As an example, when pad 30 has a circular cross-section in a plane parallel to bottom surface 28, distance “a” may correspond to the diameter of the cross-section and when pad 30 has a square cross-section in a plane parallel to bottom surface 28, distance “a” may correspond to the side of the cross-section. Pad 30 may have a generally cylindrical shape, with a cross-section of pad 30 which does not substantially vary according to the distance to bottom surface 28. As a variation, the cross-section of pad 30 may vary according to the distance to bottom surface 28. As an example, pad 30 may have a conical or frustoconical general shape.

Call pitch “λ” the distance separating the centers of two adjacent pads 30 measured in a plane parallel to bottom surface 28. According to an embodiment, pads 30 are advantageously substantially regularly distributed in peripheral area 26. According to an embodiment, pitch “λ” is substantially equal to twice dimension “a” of pads 30.

The dimensions of pads 30 are selected so that liquid drop 44 substantially rests on the tops of pads 30 without penetrating between pads 30. In particular, height “H” is sufficiently high and pitch “λ” is sufficiently low for the liquid drop 44 deposited on pads 30 not to “impale” on pads 30 and not to come into contact with bottom surface 28. This is obtained when height “H” and pitch “λ” respect the following relation (1):

$$H > \frac{λ \vert tan ( {θ}_{E} ) \vert}{π} \qquad [ Eq . 1 ]$$

According to an embodiment, a partial impaling of liquid drop 44 on pads 30 may be authorized.

When liquid drop 44 substantially rests on the tops of pads 30, the static contact angle “θ_{C}” of liquid drop 44 which is measured is greater than the static contact angle “θ_{E}” which is obtained when the liquid drop is arranged on a planar surface formed of the same material as the material at the surface of pads 30.

There exists a plurality of laws, called Cassie laws or Cassie-Baxter laws, which couple the static contact angles “θ_{C}” and “θ_{E}” and which particularly depend on the relative surface area of pads 30. As an example, for pads 30 having flat tops, static contact angles “θ_{C}” and “θ_{E}” are coupled by the following relation (2):

cos(θ_{C})=−1+f(1+cos(θ_{E})) [Eq. 2]

where f is the ratio, in top view, of the surface area occupied by pads 30 in contact with drop 44 to the surface area of the base of drop 44.

In the case where pads 30 are cylindrical with a square base, as shown as an example in FIGS. 8 and 9, static contact angles “θ_{C}” and “θ_{E}” are coupled by the following relation (3):

$$cos ( {θ}_{C} ) = - 1 + \frac{{a}^{2}}{{λ}^{2}} ( 1 + cos ( {θ}_{E} ) ) \qquad [ Eq . 3 ]$$

According to an embodiment, pitch “λ” is in the range from 300 nm to 20 μm. According to an example, the height “H” of pads 30 is greater than 430 nm for a pad width “a” of 500 nm, which corresponds to a pitch “λ” of 1 μm. According to an example, the height “H” of pads 30 is greater than 4.3 μm for a pad width “a” of 5 μm, which corresponds to a pitch “λ” of 10 μm. Such dimensions are compatible with the dimensions of the pads conventionally formed for the hybrid molecular bonding of electronic circuits.

In the embodiment illustrated in FIGS. 4 and 5, pads 30 are substantially regularly distributed in peripheral area 26 and pads 34 are substantially regularly distributed in assembly area 24. In the present embodiment, pads 30 are arranged in assembly area 26 in rows and in columns. As a variation, pads 30 may be arranged in rows, each row of pads being offset with respect to the adjacent rows.

For the CMP step to take place properly, according to an embodiment, the surface area of the metal surfaces exposed in top view on the upper surface of electronic circuit 20 obtained after the CMP step is smaller than 50%, preferably in the range from 15% to 30%, of the surface area of the upper surface. According to an embodiment, on assembly area 24, the exposed surface area of pads 34 is smaller than 50%, preferably in the range from 15% to 30%, of the surface area of assembly area 24. According to an embodiment, on peripheral area 26, in top view, the surface area of pads 30 is smaller than 50%, preferably in the range from 15% to 30%, of the surface area of peripheral area 26. According to an embodiment, since peripheral area 26 does not take part in the bonding, there are fewer constraints relative to the ratio of the surface area of the exposed pads in top view to the surface area of peripheral area 26 which, for example, may be different from that of assembly area 24, particularly smaller than 50%.

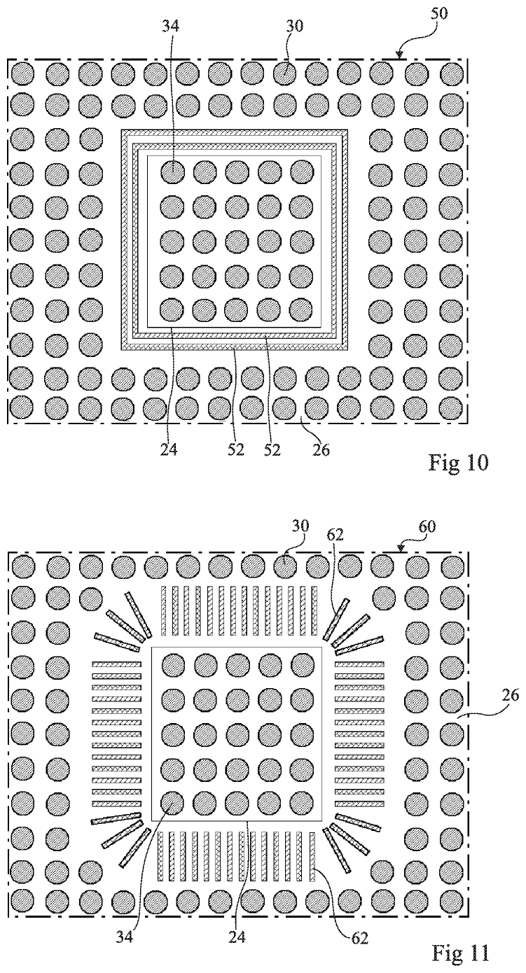

FIG. 10 is a partial simplified top view of another embodiment of a first electronic circuit 50 having at least one second electronic circuit, not shown, for example, an integrated circuit chip, intended to be affixed thereto by a method of self-assembly with a hybrid bonding. Electronic circuit 50 comprises all the elements of the electronic circuit 20 previously described in relation with FIGS. 4 and 5 and further comprises, in peripheral area 26, conductive tracks 52 totally surrounding assembly area 24. As an example, two tracks 52 are shown in FIG. 10. However, a single track 52 surrounding assembly area 24 may be present or more than two tracks 52 surrounding assembly area 24 may be present. Tracks 52 preferably have the same composition as pads 30. According to an embodiment, the width of tracks 52 may be smaller or greater than the previously-described dimension “a” of pads 30. Tracks 52 are shown as being continuous in FIG. 10. As a variation, tracks 52 may be interrupted.

Tracks 52 play the role of a barrier to decrease risks for a drop of liquid present on assembly area 24 to leave, totally or partly, assembly area 24 during the implementation of the self-assembly method. Further, tracks 52 may enable to decrease the wettability of peripheral area 26 by having a larger extended surface area than that obtained with pads 30.

FIG. 11 is a partial simplified top view of another embodiment of a first electronic circuit 60 having at least one second electronic circuit, not shown, for example, an integrated circuit chip, intended to be affixed thereto by a method of self-assembly with a hybrid bonding. Electronic circuit 60 comprises all the elements of the electronic circuit 20 previously described in relation with FIGS. 4 and 5 and further comprises, in peripheral area 26, bars 62, arranged around assembly area 24, extending substantially orthogonally to the edges of assembly area 24, except for the bars 62 located at the corners of assembly area 24 which may extend substantially radially with respect to the corners. Bars 62 preferably have the same composition as pads 30. According to an embodiment, the width of bars 62 may be smaller or greater than the previously-described dimension “a” of pads 30. According to an embodiment, the length of each bar 62 is greater than or equal to 10 times the width of bar 62.

Bars 62 play the role of guides to improve the displacement of a liquid drop towards assembly area 24 when the liquid drop is placed partly on assembly area 24 and partly on peripheral area 26. Further, bars 62 may enable to decrease the wettability of peripheral area 26 by having a larger extended surface area than that obtained with pads 30.

In the embodiments illustrated in FIGS. 10 and 11, conductive tracks 52 or bars 62 are provided in peripheral area 26 in addition to pads 30. Different expressions have been used only to ease the distinction between the different elements shown in the drawings. It should however be clear that the conductive tracks and the conductive bars may also be called pads. Generally, any type of raised structure, generically called “pads”, may be provided in peripheral area 26, each of these structures taking part in increasing the wettability difference between peripheral area 26 and the associated assembly area 24 and having at least partly the same composition as pads 34.

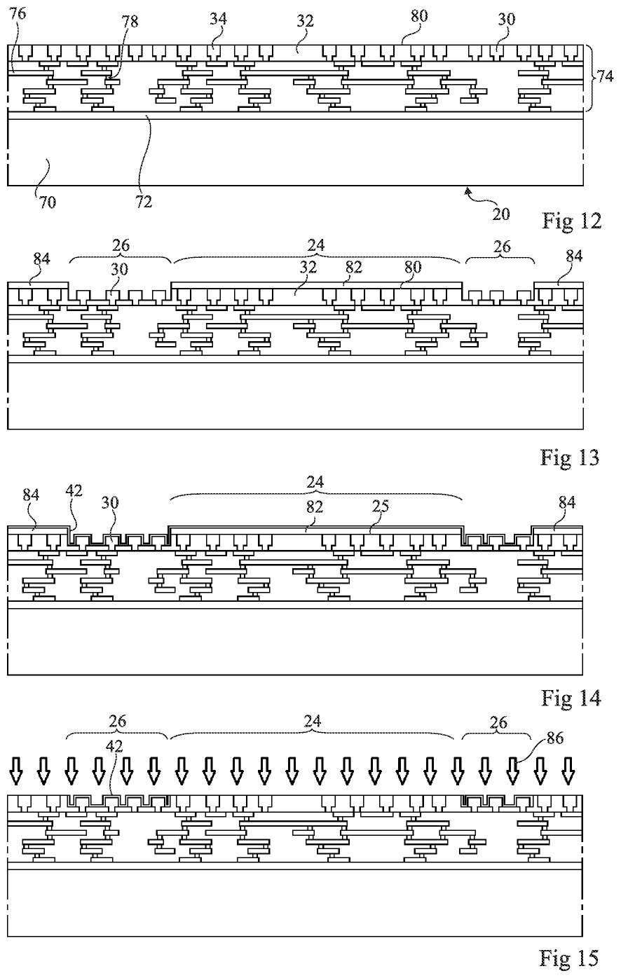

FIGS. 12 to 18 are partial simplified cross-section views of structures obtained at successive steps of an embodiment of a method of manufacturing an electronic device comprising a first electronic circuit having a second electronic circuit affixed thereto by a method of self-assembly with a hybrid molecular bonding.

FIG. 12 shows first electronic circuit 20. FIGS. 12 to 18 show the first electronic circuit 20 comprising a semiconductor substrate 70 having electronic components formed inside and on top of it, which is schematically illustrated by region 72, substrate 70 being covered with a stack 74 of insulating layers having conductive tracks 76 formed therebetween and having conductive vias 78 formed therethrough. Insulating layer 32 corresponds to the last insulating layer of stack 74, the most distant from 70. Electronic circuit 20 comprises an upper surface 80 which corresponds to the free surface area of insulating layer 32. Conductive pads 30 and 34 are flush with surface 80. Conductive pads 30 and 34 thus correspond to conductive tracks 76 of the last metallization level. The obtaining of surface 80 is achieved by a CMP step. At this stage of the manufacturing method, pads 30 have the same composition as pads 34.

FIG. 13 shows the structure obtained after the forming on surface 80, by lithography steps, of a resin layer 82 at the desired location of assembly area 24 and of a resin layer 84 outside of the desired location of peripheral area 26 and after the etching of insulating layer 32 across all or part of its thickness in peripheral area 26 to expose a portion of the pads 30 present in this area. This step simultaneously enables to delimit assembly area 24 and peripheral area 26. The etching of insulating layer 32 may be an etching implementing a plasma, particularly a plasma based on carbon tetrafluoride (CF₄) or on octofluorocyclobutane (C₄F₈), or may be a wet etching, particularly by means of a solution of hydrofluoric acid (HF), for example at a 0.25% dilution. The etching is at least partially selective over the material forming pads 30. However, the etching of insulating layer 32 may cause a slight etching of pads 30. The desired aspect ratio of pads 30, that is, the ratio between the width “a” and the height “H” of pads 30, may be controlled by the depth of the etching.

FIG. 14 shows the structure obtained after the forming of layer 42 of the hydrophobic material. Layer 42 may be deposited by implementing a plasma based on CF4 or by spin coating in the case of a liquid hydrophobic layer. The method of deposition of hydrophobic layer 42 may also cause the deposition of this layer on resin layers 82, 84. When this step is present, pads 30 are preferably slightly etched during the previously-described step of etching pads 30 so that the obtained final structure of pads 30 comprising hydrophobic layer 42 does not rise higher than the plane containing upper surface 25 of assembly area 24.

FIG. 15 shows the structure obtained after the removal of resin layers 82, 84, for example, by a liquid chemical method, and after the forming of an activation treatment to increase the wettability of assembly 24. The treatment may comprise a plasma treatment (illustrated by arrows 86) or a chemical treatment. Hydrophobic layer 42 is thus kept on the pads 30 of peripheral area 26. The activation treatment may not be present.

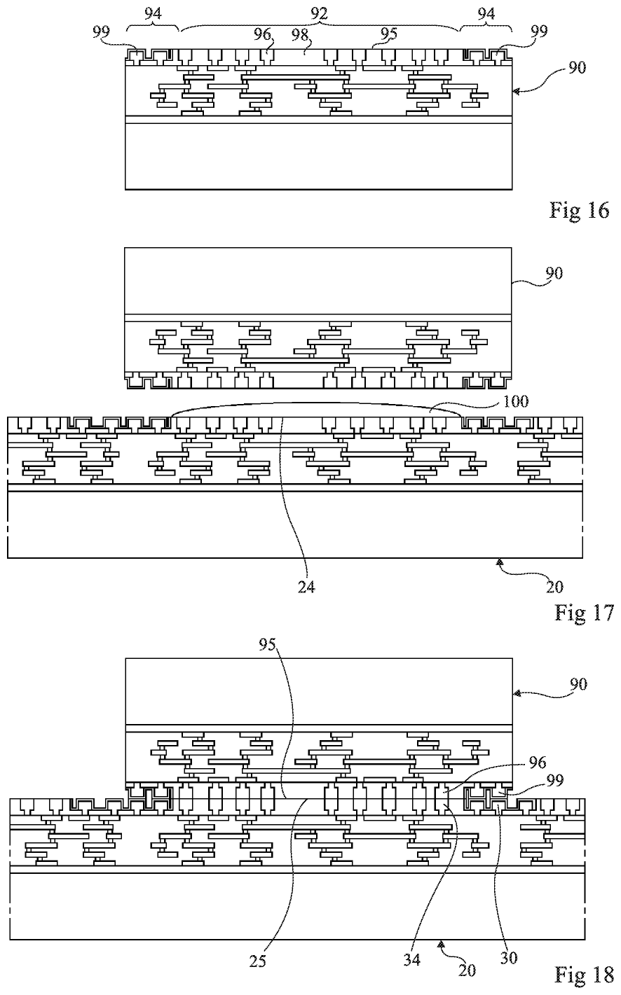

FIG. 16 shows the structure obtained after the forming of a second electronic circuit 90. Second electronic circuit 90 may be formed by the implementation of the steps previously described in relation with FIGS. 12 to 15 and after a cutting step to delimit second circuit 90. In particular, electronic circuit 90 comprises an assembly area 92, having a structure similar to the assembly area 24 of first electronic circuit 20, possibly surrounded with a peripheral area 94 having a structure similar to the peripheral area 26 of first electronic circuit 20. Assembly area 92 particularly comprises an assembly surface 95 and pads 96 separated by an insulating layer 98 and peripheral area 94 particularly comprises protruding pads 99. If the cutting technology has a sufficient accuracy, second electronic circuit 90 may only comprise assembly area 92.

FIG. 17 shows the structure after the deposition of a liquid drop 100 on the assembly area 24 of first electronic circuit 20.

FIG. 18 shows the structure after the placing into contact of second electronic circuit 90 with liquid drop 92, which causes a self-assembly of second electronic circuit 92 on first electronic circuit 20 with, on evaporation of liquid drop 92, a molecular bonding of electronic circuit 90 to electronic circuit 20. Preferably, the pads 96 of the assembly area 92 of second electronic circuit 90 are arranged symmetrically with respect to the pads 34 of the assembly area 24 of first electronic circuit 20, so that pads 96 come into contact with pads 34 during the molecular bonding step.

The pads 99 of the peripheral area 94 of second electronic circuit 90 are preferably arranged symmetrically with respect to the pads 30 of the peripheral area 26 of first electronic circuit 20, so that pads 99 can come into contact with pads 30 during the molecular bonding step. According to another embodiment, the pads 99 of the peripheral area 94 of second electronic circuit 90 may be arranged non-symmetrically with respect to the pads 30 of the peripheral area 26 of first electronic circuit 20, so that pads 99 do not come into contact with pads 30 during the molecular bonding step. According to another embodiment, the tops of the pads 99 of the peripheral area 94 of second electronic circuit 90 are recessed with respect to assembly surface 95 and/or the tops of the pads 30 of the peripheral area 26 of first electronic circuit 20 are recessed with respect to assembly surface 25, so that pads 99 do not come into contact with pads 30 during the molecular bonding step.

The CMP method may result in the obtaining of an assembly area 24, 92, before the bonding step, for which pads 34, 96 are slightly recessed with respect to the exposed planar surface of insulating layer 32, 98. During the placing into contact of second electronic circuit 90 and of first electronic 20, for example, at room temperature, the molecular bonding first takes place only between the insulating layer 32 of first electronic circuit 20 and the insulating layer 98 of second electronic circuit 90. An anneal step may then be carried out, for example at approximately 400° C. This step causes the expansion of pads 34 and 96 so that pads 96 come into contact with pads 34. A molecular bonding is then obtained between pads 96 and pads 34.

Various embodiments and variants have been described. Those skilled in the art will understand that certain features of these various embodiments and variants may be combined, and other variants will occur to those skilled in the art. In particular, although in the previously-described embodiments, the pads 30 of peripheral area 26 are shown as being separate, adjacent pads 30 may be coupled to each other by a narrow branch made of the same material as the pads. Further, although the previously-described embodiments concern an electronic device which comprises the stack of two electronic circuits, it should be clear that the electronic device may comprise a stack of more than two electronic circuits, where the previously-described embodiments may apply to each interface between two adjacent electronic circuits of the stack.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A first electronic circuit comprising a first planar surface, intended to be affixed to a second electronic circuit by a self-assembly method with a hybrid molecular bonding, and first electrically-conductive pads exposed on the first surface, the first electronic circuit further comprising a peripheral area around the first surface comprising second exposed and raised pads, each at least partly having the same composition as the first pads.

2. The first electronic circuit according to claim 1, wherein the second pads each comprise a hydrophobic coating.

3. The first electronic circuit according to claim 1, wherein the second pads are arranged all around the first surface.

4. The first electronic circuit according to claim 1, wherein the peripheral area comprises at least one raised track surrounding the first surface, the track at least partly having the same composition as the first pads.

5. The first electronic circuit according to claim 1, wherein the peripheral area comprises, around the first surface, raised bars extending perpendicularly to the edges of the first surface, each bar at least partly having the same composition as the first pads.

6. The first electronic circuit according to claim 1, wherein the tops of the second pads are recessed with respect to the first surface.

7. The first electronic circuit according to claim 1, wherein the ratio of the surface area of the first pads, seen perpendicularly to the first surface, to the surface area of the first surface is different from the ratio of the surface area of the second pads, seen perpendicularly to the peripheral area, to the surface area of the peripheral area.

8. A method of manufacturing a first electronic circuit comprising a first planar surface, intended to be affixed to a second surface of a second electronic circuit by a self-assembly method with a hybrid molecular bonding, and first electrically-conductive pads exposed on the first surface, the method comprising the forming of a peripheral area around the first surface comprising second exposed and raised pads, each at least partly having the same composition as the first pads.

9. The method according to claim 8, comprising a step of chemical mechanical planarization to form a third planar surface of an electrically-insulating layer having the first pads and the second pads exposed thereon and a step of etching the insulating layer around the second pads to delimit the first surface.

10. The method according to claim 9, comprising a step of covering the first surface with a resin layer, the deposition of a hydrophobic layer on the second pads, and the removal of the resin layer.

11. A method of self-assembly with a hybrid bonding of the first planar surface of a first electronic circuit manufactured according to the method according to claim 8 to a second surface of a second electronic circuit, the second electronic circuit comprising third electrically-conductive pads (96) exposed on the second surface, the method comprising the deposition of a drop of a liquid on the first surface and the placing into contact of the second surface with said drop.

12. The method according to claim 11, wherein the third pads are arranged symmetrically with respect to the first pads.
